(19) United States
(12) Patent Application Publication
(10) Pub. No.: US 2016/0293789 A1
(43) Pub. Date: Oct. 6, 2016

(54) VAPOR DEPOSITION EQUIPMENT INCLUDING A SELENIZATION PROCESS FOR FABRICATING CIGS FILM

(71) Applicant: NATIONAL CHUNG SHAN INSTITUTE OF SCIENCE AND TECHNOLOGY, TAOYUAN (TW)

(72) Inventors: Wen-Chueh Pan, LONGTAN/TAOYUAN (TW); Tsang-Ming Hsu, LONGTAN/TAOYUAN (TW); Jen-Chieh Li, LONGTAN/TAOYUAN (TW); Tsan-Tung Chen, LONGTAN/TAOYUAN (TW); Chui-Yu Chiu, LONGTAN/TAOYUAN (TW); Shih-Shan Wei, LONGTAN/TAOYUAN (TW)

(21) Appl. No.: 15/185,076

(22) Filed: Jun. 17, 2016

Related U.S. Application Data
(63) Continuation-in-part of application No. 14/054,905, filed on Oct. 16, 2013.

(51) Int. Cl. H01L 31/18; C23C 16/54; C23C 16/52; C23C 16/46; G01N 23/22; C30B 25/08; C30B 25/02; C30B 25/16; C30B 29/46; C23C 16/06; C30B 25/10

(52) U.S. Cl. CPC H01L 31/18; C23C 16/06; C23C 16/545; C23C 16/52; C23C 16/46; C23C 16/463; C30B 25/10; C30B 25/08; C30B 25/025; C30B 25/16; C30B 29/46; G01N 23/22; H01L 31/0322

(57) ABSTRACT

The present disclosure relates to a vapor deposition equipment for fabricating CIGS film, in which a Se vapor deposition module, a In/Ga linear vapor deposition module and a Cu linear vapor deposition module are integrated in an identical vacuum chamber, used for fabricating the CIGS absorber layers on a flexible solar cell substrate by an automatic manufacturing process in accordance with an unwinding module, a heating device, a heat reducing device, a speed-controlling roller module, a cooling module, and a winding module. Moreover, in the present disclosure, a film thickness measuring module is used for measures the thickness of the CIGS chalcopyrite crystalline film on the flexible solar cell substrate, and the thickness data of the CIGS chalcopyrite crystalline film would be transmitted to the electromechanical control module for being references of the parameter modulation of following fabricating process, and such way is so-called APC (Advanced Process Control) system.

### REFERENCE TO RELATED APPLICATIONS

This application is a continuation-in-part of U.S. patent application Ser. No. 14/054,905 filed on Oct. 16, 2013 and published as U.S. Patent Application Publication No. US 20150101534a1 on Apr. 16, 2015.

The above referenced application, and each document cited or referenced in the above referenced application, are hereby incorporated herein by reference.

### BACKGROUND OF THE DISCLOSURE

1. Technical Field

The present disclosure relates to a fabrication equipment of absorber layer, and more particularly to a vapor deposition equipment including a selenization process for fabricating CIGS films.

2. Description of Related Art

Solar cell can be divided into silicon solar cell, compound solar cell, and organic solar cell, wherein the III-V semiconductor compound is widely applied in solar cell, and the solar cell made of single junction GaAs compound performs a better photoelectric conversion efficiency of 26.1±0.8%. However, the solar cell made of multi junction semiconductor compound, for example, GaInP/GaAs/Ge compound, which performs the highest photoelectric conversion efficiency of 32±1.5% than the photoelectric conversion efficiency of the single junction GaAs compound.

Cu/In/Ga/Se (CIGS) is one kind of thin film solar cell and consists of a plurality of semiconductor materials having a variety direct band gaps, wherein the direct band gaps of the semiconductor materials are ranged from 1.04 eV to 1.68 eV. So that, because having the advantages of high light absorption coefficient, broad light absorption range, low manufacture cost, high stability, and high photoelectric conversion efficiency, the CIGS thin film solar cell is currently a popular solar cell with high potentiality. Please refer to FIG. 1, which illustrates the framework diagram of the CIGS thin film solar cell. As shown in FIG. 1, the CIGS solar cell 1′ consists of: a substrate 10′, a Mo electrode 11′, a CIGS absorber layer 12′, a CdS buffer layer 13′, a pure ZnO layer 14, a ZnO window layer 15, and a plurality of top electrodes 16′. Generally, the substrate 10′ can be made of a glass material, a thin metal sheet, or a plastic, therefore the CIGS absorber layer 12′, can be largely formed on the flexible substrate 10′ by way of vapor deposition, coating, or print.

However, although the CIGS solar cell includes the advantages of high light absorption coefficient, broad light absorption range, low manufacturing cost, and high stability, there is no a standard manufacturing equipment and the related process procedure for fabricating the CIGS solar cell. On the other hand, the cost of commercial CIGS solar cell is still high due to its poor yield and low photoelectric conversion efficiency, wherein the primary issue is how to largely fabricate the CIGS absorber layer of the CIGS solar cell by using a mass production equipment.

Accordingly, in view of there is no a standard manufacturing equipment and the related process procedure for largely fabricating the CIGS absorber layer of the CIGS solar cell, the inventor of the present application has made great efforts to make inventive research thereon and eventually provided a vapor deposition equipment including a selenization process for fabricating CIGS film.

### BRIEF SUMMARY OF THE DISCLOSURE

The primary objective of the present disclosure is to provide a vapor deposition equipment including a selenization process for fabricating CIGS film, in which a Se vapor deposition module, a In/Ga linear vapor deposition module and a Cu linear vapor deposition module are integrated in an identical vacuum chamber, used for fabricating the CIGS absorber layers on a flexible solar cell substrate by an automatic manufacturing process in accordance with a winding module, a heating device, a heat reducing device, a speed-controlling roller module, a cooling module, and an unwinding module. Moreover, in the present disclosure, a film thickness measuring module is used for measures the thickness of the CIGS chalcopyrite crystalline film on the flexible solar cell substrate, and the thickness data of the CIGS chalcopyrite crystalline film would be transmitted to the electromechanical control module for being references of the parameter modulation of following fabricating process, and such way is so-called APC (Advanced Process Control) system.

Accordingly, to achieve the primary objective of the present disclosure, the inventor of the present disclosure provides a vapor deposition equipment including a selenization process for fabricating CIGS film, comprising:

a vacuum chamber , having a vacuum interior formed by using a vacuum pump;

an unwinding module, being disposed in the vacuum chamber and having an unwinding roller unload with a flexible solar cell substrate;

a heating module, being disposed in the vacuum chamber and having two heating device adjacent to a flexible solar cell substrate, which the heating device is located over the flexible solar cell substrate surface, wherein the unwinding module feeds the flexible solar cell substrate to the heating module for heating the flexible solar cell substrate surface;

a first vapor deposition chamber, being disposed in the vacuum chamber, and having a heating device for deposition a Copper, Indium, gallium and selenium, and having a first In/Ga linear vapor deposition module and a first copper linear vapor deposition module in the first vapor deposition chamber being separated by a first partition plate; wherein an excessive selenium (Se) vapor is flowed into the first In/Ga linear vapor deposition module and the first copper linear vapor deposition module and the other part of heating device is located over the flexible solar cell substrate, so as to the flexible solar cell substrate can be heated to over 550° C. and make a CIGS chalcopyrite crystalline film be formed on the flexible solar cell substrate through the first In/Ga linear vapor deposition module and the first copper linear vapor deposition module;

a second vapor deposition chamber, being disposed in the vacuum chamber, and having a heating device for deposition a Copper, Indium, gallium and selenium, and having a second In/Ga linear vapor deposition module and a second copper linear vapor deposition module in the second vapor deposition chamber being separated by a second partition plate; wherein the excessive selenium (Se) vapor is flowed into the second In/Ga linear vapor deposition module and the second copper linear vapor deposition module, so as to make an optimized CIGS chalcopyrite crystalline film be formed on the flexible solar cell substrate through the second In/Ga linear vapor deposition module and the second copper linear vapor deposition module;

a heat reducing device, being disposed in the vacuum chamber and adjacent to the second vapor deposition chamber, used for preventing the optimized CIGS chalcopyrite crystalline film on the flexible solar cell substrate from cracking due to the residual thermal stress resulted from the rapid temperature change;

a speed-controlling roller module, being disposed in the vacuum chamber and opposite to the unwinding module, wherein a main roller of the speed-controlling roller module is utilized to control the speed of the flexible solar cell substrate formed with the optimized CIGS chalcopyrite crystalline film thereon, so as to control the conveying precise speed of the flexible solar cell substrate. On the other hand, while both the servo motor drive winding and unwinding rollers can thus building tension along the substrate. A load cell is utilized in order to monitor the tension force of the flexible solar cell substrate in the vacuum chamber and thus the tension of the substrate can be precisely controlled;

a cooling module, being disposed in the vacuum chamber and opposite to the heating module, wherein the flexible solar cell substrate formed with the optimized CIGS chalcopyrite crystalline film is transmitted to the cooling module by the speed-controlling roller module for cooling; and

a winding module, being disposed in the vacuum chamber and adjacent to the unwinding module via an isolation plate, wherein a winding roller of the winding module rolls up with the flexible solar cell substrate formed with the optimized CIGS chalcopyrite crystalline film for receiving.

### BRIEF DESCRIPTION OF THE SEVERAL VIEWS OF THE DRAWINGS

The disclosure as well as a preferred mode of use and advantages thereof will be best understood by referring to the following detailed description of an illustrative embodiment in conjunction with the accompanying drawings, wherein:

FIG. 1 is a framework diagram of a conventional CIGS thin film solar cell;

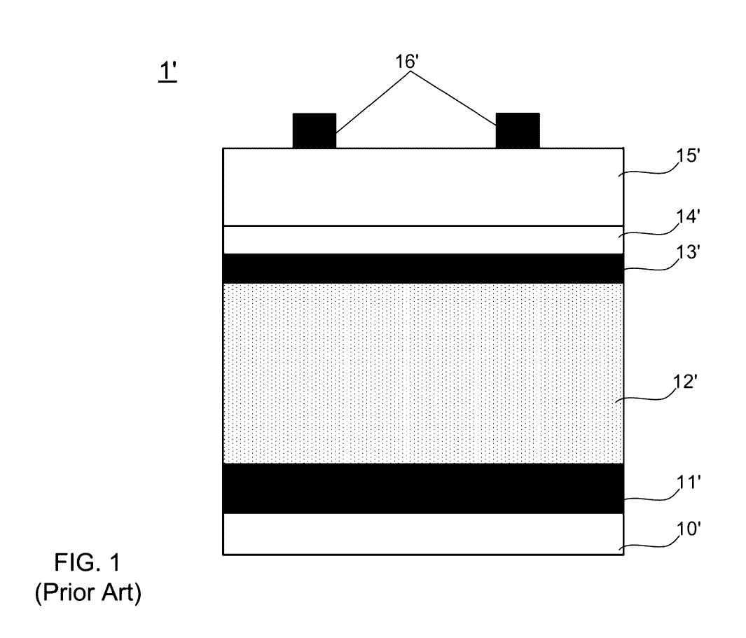

FIG. 2 is framework diagram of a vapor deposition equipment including a selenization process for fabricating CIGS film according to the present disclosure;

FIG. 3 is a temperature distribution plot of a flexible solar cell substrate;

FIG. 4 is a schematic diagram for torque (F) of a serve motor of a main roller;

FIG. 5 is schematic free body force diagram for the flexible solar cell substrate on the main roller.

### DETAILED DESCRIPTION OF THE DISCLOSURE

To more clearly describe a vapor deposition equipment including a selenization process for fabricating CIGS film according to the present disclosure, embodiments of the present disclosure will be described in detail with reference to the attached drawings hereinafter.

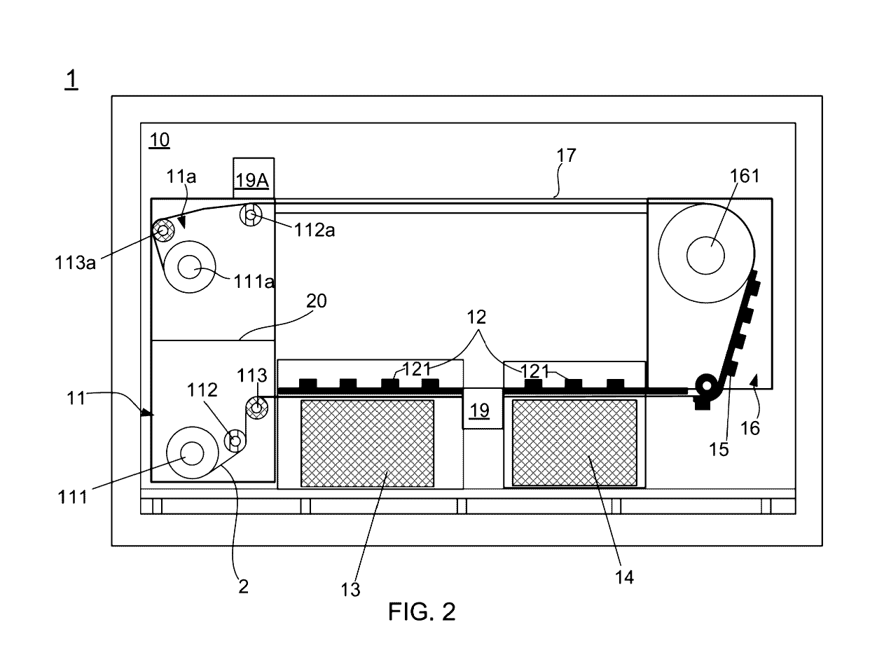

Please refer to FIG. 2, which illustrates a framework diagram of a vapor deposition equipment including a selenization process for fabricating CIGS film according to the present disclosure. As shown in FIG. 2, the vapor deposition equipment 1 consists of: a vacuum chamber 10, an unwinding module 11, a heating module 12, a first vapor deposition chamber 13, a film thickness measuring module 19, a second vapor deposition chamber 14, a heat reducing device 15, a speed-controlling roller module 16, a cooling module 17, a winding module 11a, an electromechanical control module, and a chemical compound composition measuring module 19a; wherein a vacuum interior is formed in the vacuum chamber 10 by using a vacuum pump.

The unwinding module 11 is disposed in the vacuum chamber 10 and has an unwinding roller 111 unloaded a flexible solar cell substrate 2. In addition, the unwinding module 11 further includes an unwinding tension pulley 112 and an edge detecting device 113, wherein the unwinding tension pulley 112 is used for detecting the tension of the flexible solar cell substrate 2 and then adjusting the tension of the flexible solar cell substrate 2 when the flexible solar cell substrate 2 is fed out by the unwinding roller 111, and the edge detecting device 113 is disposed in the vacuum chamber 10 and used for detecting the edge position of the flexible solar cell substrate 2, so as to control the unwinding roller 111 adjust the edge position of the flexible solar cell substrate 2 when the flexible solar cell substrate 2 is fed out by the unwinding roller 111.

Opposite to the unwinding module 11, the winding module 11a is disposed in the vacuum chamber 10 and adjacent to the unwinding module 11 via an isolation plate 20, wherein the isolation plate 20 is used for preventing the Se vapor from flowing into the winding module 11a. In the present disclosure, a winding roller 111a of the winding module 11a is used to roll up with the flexible solar cell substrate 2 formed with an optimized CIGS chalcopyrite crystalline film for receiving. Besides, the winding module 11 a further includes a winding tension pulley 112a and an edge detecting device 113a, wherein the winding tension pulley 112a is used for detecting the tension of the flexible solar cell substrate 2 and then adjusting the tension of the flexible solar cell substrate 2 when the flexible solar cell substrate 2 is rolled up by the winding roller 111a, and the edge detecting device 113a is used for detecting the edge position of the flexible solar cell substrate 2, so as to control the winding roller 111a adjust the edge position of the flexible solar cell substrate 2 when the flexible solar cell substrate 2 is rolled up by the winding roller 111a.

Herein, it needs to further explain that, both the unwinding module 11 and the winding module 11a at least have a serve motor, which is used for precisely control the tension of the flexible solar cell substrate 2 via the unwinding tension pulley 112 and the winding tension pulley 112a. Moreover, in the present disclosure, a main roller 161 of the speed-controlling roller module 16 is utilized to control the speed of the flexible solar cell substrate 2 formed with the optimized CIGS chalcopyrite crystalline film thereon, so as to control the conveying precise speed of the flexible solar cell substrate. On the other hand, while both the servo motor drive winding and unwinding rollers can thus building tension along the substrate. A load cell is utilized in order to monitor the tension force of the flexible solar cell substrate 2 in the vacuum chamber 10 and thus the tension of the substrate can be precisely controlled, and control the feeding-out speed of the unwinding module 11 and unwinding speed of the winding module 11a at the same time. Therefore, the unwinding module 11 is able to feed the flexible solar cell substrate 2 to the heating module 12 for treating a heating process by a linear feeding-out speed.

Moreover, in the present disclosure, the heating module 12 is disposed in the vacuum chamber 10 and having two heating device 121 adjacent to a flexible solar cell substrate 2, which the heating device 121 is located over the flexible solar cell substrate 2 surface, wherein the unwinding module 11 feeds the flexible solar cell substrate 2 to the heating module 12 for heating the flexible solar cell substrate 2 surface.

Continuously, as shown in FIG. 2, the first vapor deposition chamber 13 is disposed in the vacuum chamber 10, and having a heating device for deposition a Copper, Indium, gallium and selenium, and having a first In/Ga linear vapor deposition module and a first copper linear vapor deposition module in the first vapor deposition chamber 13 being separated by a first partition plate. When the vapor deposition equipment 1 of the present disclosure is operated for fabricating a CIGS film, the flexible solar cell substrate 2 is conveyed to the operation region of the heating module 12 for being treating with a first heating process; therefore, the heated flexible solar cell substrate 2 is next transmitted into the first vapor deposition chamber 13, and then an excessive selenium (Se) vapor is flowed into the first In/Ga linear vapor deposition module and the first copper linear vapor deposition module, so as to the flexible solar cell substrate 2 can be heated to over 550° C. and make a CIGS chalcopyrite crystalline film be formed on the flexible solar cell substrate 2 through the first In/Ga linear vapor deposition module and the first copper linear vapor deposition module and make a CIGS chalcopyrite crystalline film composited by a In/Ga/Se compound semiconductor and a Cu/Se compound semiconductor.

Herein, it needs to further explain that, besides the Se vapor, the vapor flowed into the first In/Ga linear vapor deposition module and the first copper linear vapor deposition module can also be Te vapor in order to fabricate a different absorber layer on the flexible solar cell substrate 2. Moreover, the metal compound deposited by the first In/Ga linear vapor deposition module can also be an In metal material or a In/Ga metal compound. In addition, besides the Cu metal material, the metal material deposited by the first copper linear vapor deposition module can also be an Al metal material. Furthermore, in this vapor deposition equipment 1, the first In/Ga linear vapor deposition module has a plurality of nozzles consisting of one indium vapor nozzle and one gallium vapor nozzle. In the present disclosure, the one indium vapor nozzle and the gallium vapor nozzle are arranged to focus at the same position on the flexible solar cell substrate 2 in the first vapor deposition chamber 13, so as to form a metal compound of In/Ga on the flexible solar cell substrate 2 by a best compound composition ratio.

Opposite to the first vapor deposition chamber 13, the second vapor deposition chamber 14 is disposed in the vacuum chamber 10, and having a heating device for deposition a Copper, Indium, gallium and selenium, and having a second In/Ga linear vapor deposition module and a second copper linear vapor deposition module in the second vapor deposition chamber 14 being separated by a second partition plate. When the vapor deposition equipment 1 of the present disclosure is operated for fabricating a CIGS film, the flexible solar cell substrate 2 formed with the CIGS chalcopyrite crystalline film is subsequently conveyed into the second vapor deposition chamber 14 and treated with a second heating process, and then an excessive selenium (Se) vapor is flowed into the second In/Ga linear vapor deposition module and the second copper linear vapor deposition module, so as to make an optimized CIGS chalcopyrite crystalline film composited by a Cu/In/Ga/Se metal compound be formed on the flexible solar cell substrate 2 through the second In/Ga linear vapor deposition module and the second copper linear vapor deposition module.

Similarly, for the second vapor deposition chamber 14, it is not only the Se vapor but also the Te vapor can be flowed into the second In/Ga linear vapor deposition module and the second copper linear vapor deposition module for fabricating a different absorber layer on the flexible solar cell substrate 2. Moreover, the metal compound deposited by the second In/Ga linear vapor deposition module can also be a In metal material or a In/Ga metal metal compound. In addition, besides the Cu metal material, the metal material deposited by the second copper linear vapor deposition module can also be an Al metal material. Furthermore, in this vapor deposition equipment 1, the second In/Ga linear vapor deposition module has a plurality of nozzles, consisting of one indium vapor nozzle and one gallium vapor nozzle. In the present disclosure, the one indium vapor nozzle and the gallium vapor nozzle are arranged to focus to the flexible solar cell substrate 2 in the second vapor deposition chamber 14, so as to form a metal compound of In/Ga on the flexible solar cell substrate 2 by a best compound composition ratio.

However, before the flexible solar cell substrate 2 is conveyed into the second vapor deposition chamber 14, a film thickness measuring module 19 located between the first vapor deposition chamber 13 and the second vapor deposition chamber 14 would measures the thickness of the CIGS chalcopyrite crystalline film on the flexible solar cell substrate 2 formed by the first In/Ga linear vapor deposition module and the first copper linear vapor deposition module. Therefore, the thickness data of the CIGS chalcopyrite crystalline film would be transmitted to the electromechanical control module for being references of the parameter modulation of following fabricating process, and such way is so-called APC (Advanced Process Control) system.

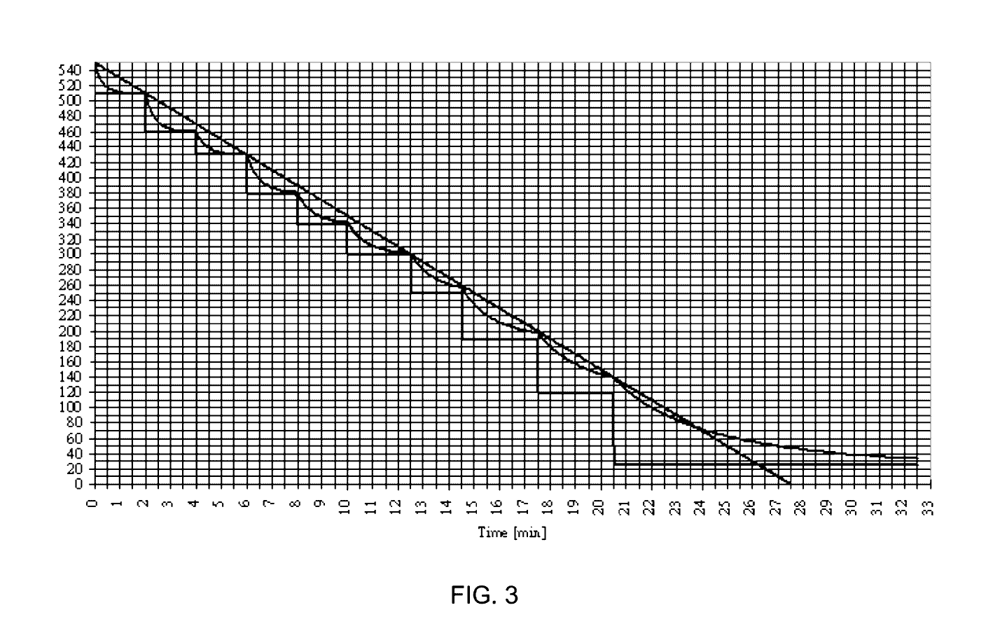

Moreover, in the present disclosure, a heat reducing device 15 is disposed in the vacuum chamber 10 and adjacent to the second vapor deposition chamber 14, used for preventing the optimized CIGS chalcopyrite crystalline film on the flexible solar cell substrate 2 from cracking due to the residual thermal stress resulted from the rapid temperature change. The heat reducing device 15 is designed and established according to the temperature distribution plot of the flexible solar cell substrate 2 shown in FIG. 3.

Because the main roller 161 of the speed-controlling roller module 16 is utilized to control the feeding-out speed of the winding module 11 and unwinding speed of the winding module 11a, the contact angle and the friction between the main roller 161 and the flexible solar cell substrate 2 must be analyzed and discussed. Please refer to following table 1, which records the analysis results under three different contact angles of 60o, 90 o and 180 o. From table 1, it can find that the critical friction coefficient μ is inversely proportional to the contact angle; and it means that the flexible solar cell substrate 2 is more and more difficult to slide on the main roller 161 with the increasing of the contact angle.

TABLE 1

| | Contact angle | Contact angle | Contact angle |
|---|---|---|---|
| | (90o) | (180o) | (60o) |
| Pressure (P) | $\frac{{F}_{2} + {F}_{1}}{2 r}$ | $\frac{{F}_{2} + {F}_{1}}{2 r}$ | $\frac{{F}_{2} + {F}_{1}}{2 r}$ |
| Torque (Γ) | (F₂ − F₁)r | (F₂ − F₁)r | (F₂ − F₁)r |
| Maximum of force moment | $\frac{μ π r ( {F}_{2} + {F}_{1} )}{4}$ | $\frac{μ π r ( {F}_{2} + {F}_{1} )}{2}$ | $\frac{μ π r ( {F}_{2} + {F}_{1} )}{6}$ |
| critical friction coefficient | $μ > \frac{4}{π} \frac{{F}_{2} - {F}_{1}}{{F}_{2} + {F}_{1}}$ | $μ > \frac{2}{π} \frac{{F}_{2} - {F}_{1}}{{F}_{2} + {F}_{1}}$ | $μ > \frac{6}{π} \frac{{F}_{2} - {F}_{1}}{{F}_{2} + {F}_{1}}$ |

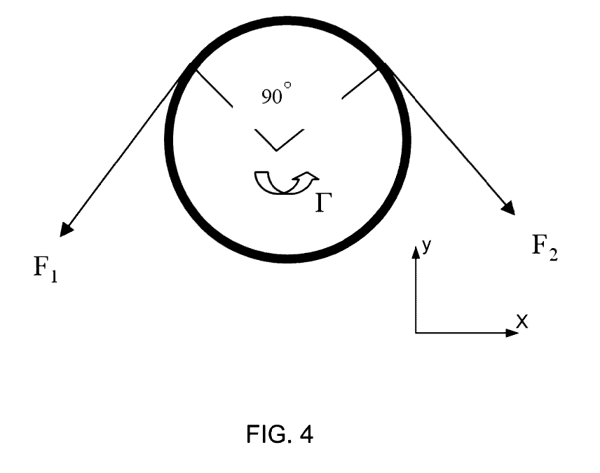

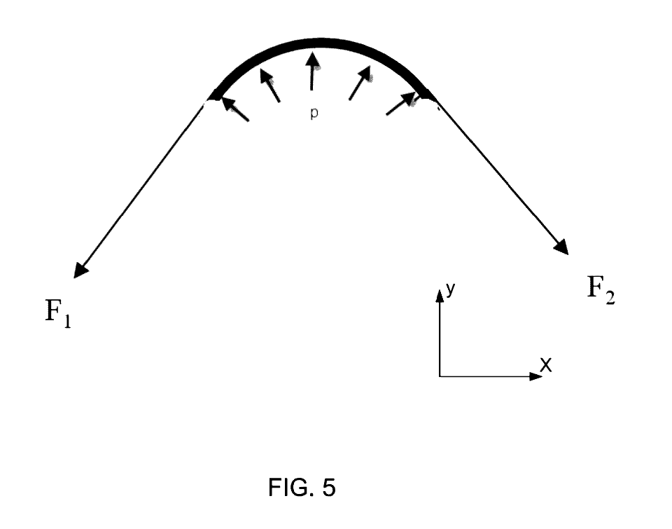

Referring to FIG. 4, which illustrates a schematic diagram for the torque (F) of the serve motor of the main roller 161; moreover, please simultaneously refer to FIG. 5, there is shown a schematic free body force diagram for the flexible solar cell substrate 2 on the main roller 161. As shown in FIG. 4, the conditions for achieving the force balance along y-axis are listed as follows:

$$\begin{matrix}2 {{\int }^{π \text{/} 4}}_{0} P cos ( 2 θ ) \cdot r \cdot cos ( θ ) d θ = 2 Pr {{\int }^{1 \text{/} \sqrt{2}}}_{0} ( 1 - 2 {sin}^{2} ( θ ) ) d sin ( θ ) = 2 Pr ( \frac{1}{\sqrt{2}} - \frac{2}{3} {( \frac{1}{\sqrt{2}} )}^{3} ) = \frac{4 pr}{3 \sqrt{2}} = \frac{{F}_{1} + {F}_{2}}{\sqrt{2}} & ( 1 ) \\ P = 0.75 \frac{{F}_{1} + {F}_{2}}{r} & ( 2 )\end{matrix}$$

By above-listed two formulas, the critical friction coefficient can be derived and obtained: μ=4(F2−F1)/3(F2+F1)=1.333(F2−F1)/(F2+F1). Moreover, from FIG. 5, it is able to know that, when a uniform pressure is applied on the flexible solar cell substrate 2 by the main roller 161, a friction force with a smallest critical friction coefficient would be produced in the interface of the flexible solar cell substrate 2 and the main roller 161; on the contrary, when a single-point pressure is applied on the flexible solar cell substrate 2 by the main roller 161, a friction force with a largest critical friction coefficient would be produced in the interface of the flexible solar cell substrate 2 and the main roller 161. Based on above reason, it is able to derive and calculate the difference of the largest critical friction coefficient and the smallest critical friction coefficient is about 10%. Therefore, the above descriptions have proved that the error between the estimated value and the actual value of the critical friction coefficient can be limited within 10% by the design of the present disclosure.

Please refer to FIG. 2 again, in which a cooling module 17 is disposed in the vacuum chamber 10 and opposite to the heating module 12. In the present disclosure, the flexible solar cell substrate 2 formed with the optimized CIGS chalcopyrite crystalline film would be transmitted to the cooling module 17 by the speed-controlling roller module 16 for cooling before being rolled-up by the winding module 11a. Thus, the winding module 11a can rolled-up the flexible solar cell substrate 2 formed with the optimized CIGS chalcopyrite crystalline film under a room temperature; moreover, a winding tension pulley 112a is used for adjusting the tension of the flexible solar cell substrate 2, and an edge detecting device 113a is used for detecting the edge position of the flexible solar cell substrate 2, so as to facilitate the winding roller 111a adjust the edge position of the flexible solar cell substrate 2.

Furthermore, a chemical compound composition measuring module 19a, for example, an XRF (X-Ray Fluorescence) device, which is disposed in the vacuum chamber 10 and located on the accommodating body of the winding module 11a, used for measuring the compound composition of the optimized CIGS chalcopyrite crystalline film on the flexible solar cell substrate 2.

Therefore, through above descriptions, the vapor deposition equipment including a selenization process for fabricating CIGS film of the present disclosure has been clearly and completely described; in summary, the present disclosure includes the advantages of:

(1) In the present disclosure, the Se vapor deposition module, In/Ga linear vapor deposition module and Cu linear vapor deposition module are integrated in an identical vacuum chamber, used for fabricating CIGS absorber layer on a flexible solar cell substrate by an automatic manufacturing process in accordance with a winding module, a heating device, a heat reducing device, a speed-controlling roller module, a cooling module, and an unwinding module. Moreover, in the present disclosure, a film thickness measuring module is used for measures the thickness of the CIGS chalcopyrite crystalline film on the flexible solar cell substrate, and the thickness data of the CIGS chalcopyrite crystalline film would be transmitted to the electromechanical control module for being references of the parameter modulation of following fabricating process, and such way is so-called APC (Advanced Process Control) system.

(2) Inheriting to above point 1, because the Se vapor deposition module, In/Ga linear vapor deposition module and Cu linear vapor deposition module are integrated in an identical vacuum chamber, the machine occupation spaces and the manufacturing time cost are largely saved; moreover, in the present disclosure, the quantity of the vacuum pump is largely reduced due to the decreasing of the requirements for vacuum environment.

The above description is made on embodiments of the present disclosure. However, the embodiments are not intended to limit scope of the present disclosure, and all equivalent implementations or alterations within the spirit of the present disclosure still fall within the scope of the present disclosure.

1. A vapor deposition equipment including a selenization process for fabricating CIGS film, comprising:
a vacuum chamber, having a vacuum interior formed by using a vacuum pump;
an unwinding module, being disposed in the vacuum chamber and having an unwinding roller unload with a flexible solar cell substrate;
a heating module, being disposed in the vacuum chamber and having two heating device adjacent to a flexible solar cell substrate, which the heating device is located over the flexible solar cell substrate surface, wherein the unwinding module feeds the flexible solar cell substrate to the heating module for heating the flexible solar cell substrate surface;
a first vapor deposition chamber, being disposed in the vacuum chamber, and having a heating device for deposition a Copper, Indium, gallium and selenium, and having a first In/Ga linear vapor deposition module and a first copper linear vapor deposition module in the first vapor deposition chamber being separated by a first partition plate; wherein an excessive selenium (Se) vapor is flowed into the first In/Ga linear vapor deposition module and the first copper linear vapor deposition module and the other part of heating device is located over the flexible solar cell substrate, so as to the flexible solar cell substrate can be heated to over 550° C. and make a CIGS chalcopyrite crystalline film be formed on the flexible solar cell substrate through the first In/Ga linear vapor deposition module and the first copper linear vapor deposition module;
a second vapor deposition chamber, being disposed in the vacuum chamber, and having a heating device for deposition a Copper, Indium, gallium and selenium, and having a second In/Ga linear vapor deposition module and a second copper linear vapor deposition module in the second vapor deposition chamber being separated by a second partition plate; wherein the excessive selenium (Se) vapor is flowed into the second In/Ga linear vapor deposition module and the second copper linear vapor deposition module, so as to make an optimized CIGS chalcopyrite crystalline film be formed on the flexible solar cell substrate through the second In/Ga linear vapor deposition module and the second copper linear vapor deposition module;
a heat reducing device, being disposed in the vacuum chamber and adjacent to the second vapor deposition chamber, used for preventing the optimized CIGS chalcopyrite crystalline film on the flexible solar cell substrate from cracking due to the residual thermal stress resulted from the rapid temperature change;
a speed-controlling roller module, being disposed in the vacuum chamber and opposite to the unwinding module, wherein a main roller of the speed-controlling roller module is utilized to control the speed of the flexible solar cell substrate formed with the optimized CIGS chalcopyrite crystalline film thereon, so as to control the conveying precise speed of the flexible solar cell substrate. On the other hand, while both the servo motor drive winding and unwinding rollers can thus building tension along the substrate. A load cell is utilized in order to monitor the tension force of the flexible solar cell substrate in the vacuum chamber and thus the tension of the substrate can be precisely controlled.
a cooling module, being disposed in the vacuum chamber and opposite to the heating module, wherein the flexible solar cell substrate formed with the optimized CIGS chalcopyrite crystalline film is transmitted to the cooling module by the speed-controlling roller module for cooling; and
a winding module, being disposed in the vacuum chamber and adjacent to the unwinding module via an isolation plate, wherein a winding roller of the winding module rolls up with the flexible solar cell substrate formed with the optimized CIGS chalcopyrite crystalline film for receiving.

2. The vapor deposition equipment including a selenization process for fabricating CIGS film of claim 1, further comprising: a film thickness measuring module, being disposed in the vacuum chamber and located between the first vapor deposition chamber and the second vapor deposition chamber, used for measuring the thickness of the CIGS chalcopyrite crystalline film on the flexible solar cell substrate formed by the first In/Ga linear vapor deposition module and the first copper linear vapor deposition module.

3. The vapor deposition equipment including a selenization process for fabricating CIGS film of claim 2, further comprising:
an electromechanical control module, being disposed on the exterior of the vacuum chamber, used for modulating manufacture process parameters and controlling the speed of the main roller of the speed-controlling roller module; and
a chemical compound composition measuring module, being disposed in the vacuum chamber and located on the accommodating body of the winding module, used for measuring the compound composition of the optimized CIGS chalcopyrite crystalline film on the flexible solar cell substrate.

4. The vapor deposition equipment including a selenization process for fabricating CIGS film of claim 1, wherein each of the first In/Ga linear vapor deposition module and the second In/Ga linear vapor deposition module have a plurality of nozzles, and the nozzles are arranged to focus to the flexible solar cell substrate in the first vapor deposition chamber and the second vapor deposition chamber, so as to form a compound metal compound of In/Ga on the flexible solar cell substrate by a best compound composition ratio.

5. The vapor deposition equipment including a selenization process for fabricating CIGS film of claim 1, wherein the unwinding module further comprising:
a unwinding tension pulley, being used for detecting the tension of the flexible solar cell substrate and then adjusting the tension of the flexible solar cell substrate when the flexible solar cell substrate is fed out by the unwinding roller; and
an edge detecting device, being disposed in the vacuum chamber and used for detecting the edge position of the flexible solar cell substrate, so as to control the unwinding roller adjust the edge position of the flexible solar cell substrate when the flexible solar cell substrate is fed out by the unwinding roller.

6. The vapor deposition equipment including a selenization process for fabricating CIGS film of claim 1, wherein the winding module further comprising:
a winding tension pulley, being used for detecting the tension of the flexible solar cell substrate and then adjusting the tension of the flexible solar cell substrate when the flexible solar cell substrate is rolled up by the winding roller; and
an edge detecting device, being used for detecting the edge position of the flexible solar cell substrate, so as to control the winding roller adjust the edge position of the flexible solar cell substrate when the flexible solar cell substrate is rolled up by the winding roller.
